(19) United States
(12) Patent Application Publication
(10) Pub. No.: US 2019/0355813 A1
(43) Pub. Date: Nov. 21, 2019

(54) SEMICONDUCTOR DEVICE INCLUDING DEVICE ISOLATION LAYER

(71) Applicant: Samsung Electronics Co., Ltd., Suwon-si (KR)

(72) Inventors: Se-myeong JANG, Gunpo-si (KR); Jun-hyeok AHN, Hwaseong-si (KR); Bong-soo KIM, Yongin-si (KR); Hyo-bin PARK, Hwaseong-si (KR); Myoung-seob SHIM, Suwon-si (KR)

(73) Assignee: Samsung Electronics Co., Ltd., Suwon-si (KR)

(21) Appl. No.: 16/217,285

(22) Filed: Dec. 12, 2018

(30) Foreign Application Priority Data
May 18, 2018 (KR) 10-2018-0057432

(51) Int. Cl. H01L 29/06; H01L 29/51; H01L 21/762

(52) U.S. Cl. CPC H01L 29/0649; H01L 21/76224; H01L 29/517; H01L 29/0696

(57) ABSTRACT

Provided are semiconductor devices including device isolation layers. The semiconductor device includes a substrate having a cell region and a core/peripheral region, a first active region in the cell region of the substrate, a first device isolation layer that defines the first active region, a second active region in the core/peripheral region of the substrate; and a second device isolation layer that defines the second active region. A height from a lower surface of the substrate to an upper end of the first device isolation layer in a first direction that is perpendicular to the lower surface of the substrate is less than or equal to a height from the lower surface of the substrate to an upper end of the first active region in the first direction.

### CROSS-REFERENCE TO RELATED APPLICATION

This application claims the benefit of Korean Patent Application No. 10-2018-0057432, filed on May 18, 2018, in the Korean Intellectual Property Office, the disclosure of which is incorporated herein in its entirety by reference.

### BACKGROUND

The inventive concepts relate to a semiconductor device, and more particularly, to a semiconductor device including a device isolation layer.

A device isolation layer may be formed to define an active region of a semiconductor device. For example, the device isolation layer may be formed by forming an insulation film that fills a trench formed in a substrate. The device isolation layer may affect electrical characteristics of the semiconductor device.

### SUMMARY

The inventive concepts provide a semiconductor device including a device isolation layer that increases electrical characteristics thereof, reduces an area of a core/peripheral region, increases a process margin of removing an oxide on an active region before forming a gate insulating film in the core/peripheral region, and increases a process margin of forming a gate structure.

According to an aspect of the inventive concepts, there is provided a semiconductor device including: a substrate having a cell region and a core/peripheral region; a first active region in the cell region of the substrate; a first device isolation layer that defines the first active region; a second active region in the core/peripheral region of the substrate; and a second device isolation layer that defines the second active region. The second device isolation layer includes a first insulating film that contacts the second active region and a second insulating film that contacts the first insulating film and is spaced apart from the first active region. A height from a lower surface of the substrate to an upper end of the first device isolation layer in a first direction that is perpendicular to the lower surface of the substrate is less than or equal to a height from the lower surface of the substrate to an upper end of the first active region in the first direction. A height from the lower surface of the substrate to an upper end of the second device isolation layer in the first direction is greater than a height from the lower surface of the substrate to an upper end of the second active region in the first direction.

According to another aspect of the inventive concepts, there is provided a semiconductor device including: a substrate having a cell region and a core/peripheral region; a first active region in the cell region of the substrate; a second active region that is separated by a first distance from the first active region in a direction parallel to a lower surface of the substrate; a third active region that is separated by a second distance which is less than the first distance from the first active region in a direction parallel to the lower surface of the substrate; a first device isolation layer that defines the first active region, the second active region, and the third active region; a fourth active region and a fifth active region separated from each other by a third distance which is greater than the first distance in a direction parallel to the lower surface of the substrate in the core/peripheral region of the substrate; and a second device isolation layer that defines the fourth active region and the fifth active region. The first device isolation layer includes a first insulating film that contacts the first active region, the second active region, and the third active region and a second insulating film surrounded by the first insulating film. The second insulating film is arranged between the first active region and the second active region. The second device isolation layer includes a third insulating film that contacts the fourth active region and the fifth active region, and a fourth insulating film that contacts the third insulating film and is separated from the fourth active region and the fifth active region. At least a portion of an upper surface of the second device isolation layer upwardly protrudes from the fourth active region and the fifth active region.

According to another aspect of the inventive concepts, there is provided a semiconductor device including: a substrate having a cell region and a core/peripheral region; a first active region in the cell region of the substrate; a first device isolation layer that defines the first active region; a second active region in the core/peripheral region of the substrate; a second device isolation layer that defines the second active region; a gate insulating film on the second active region; and a gate structure that is arranged on the gate insulating film and extend on the second device isolation layer. The first device isolation layer includes a first insulating film that contacts the first active region and a second insulating film surrounded by the first insulating film. The second device isolation layer includes a third insulating film that contacts the second active region, a fourth insulating film, sidewalls and a lower surface thereof are surrounded by the third insulating film, and a capping insulating film covering an upper surface of the fourth insulating film. A height from a lower surface of the substrate to an upper end of the second device isolation layer in a first direction that is perpendicular to the lower surface of the substrate is greater than a height from the lower surface of the substrate to an upper end of the second active region in the first direction. A height from the lower surface of the substrate to an upper end of the first active region in the first direction is greater than a height from the lower surface of the substrate to the upper end of the second active region in the first direction.

### BRIEF DESCRIPTION OF THE DRAWINGS

Embodiments of the inventive concepts will be more clearly understood from the following detailed description taken in conjunction with the accompanying drawings in which:

FIG. 1 is a plan view of a semiconductor device according to some embodiments of the inventive concepts;

FIG. 2 shows cross-sectional views taken along lines AA′, BB′, and CC′ of FIG. 1;

FIG. 3 shows cross-sectional views of a semiconductor device according to some embodiments of the inventive concepts;

FIG. 4 shows cross-sectional views of a semiconductor device according to some embodiments of the inventive concepts;

FIG. 5 shows cross-sectional views of a semiconductor device according to some embodiments of the inventive concepts;

FIGS. 6 and 7 are cross-sectional views of a semiconductor device according to some embodiments of the inventive concepts;

FIG. 8 is a plan view of a semiconductor device according to some embodiments of the inventive concepts;

FIG. 9 shows cross-sectional views taken along lines AA′, BB″, DD′, and EE′ of FIG. 8;

FIGS. 10A through 10H are cross-sectional views of a method of manufacturing a semiconductor device, according to some embodiments of the inventive concepts;

FIGS. 11A through 11I are cross-sectional views of a method of manufacturing a semiconductor device, according to some embodiments of the inventive concepts; and

FIGS. 12A through 12D are cross-sectional views of a method of manufacturing a semiconductor device, according to some embodiments of the inventive concepts.

### DETAILED DESCRIPTION OF EMBODIMENTS

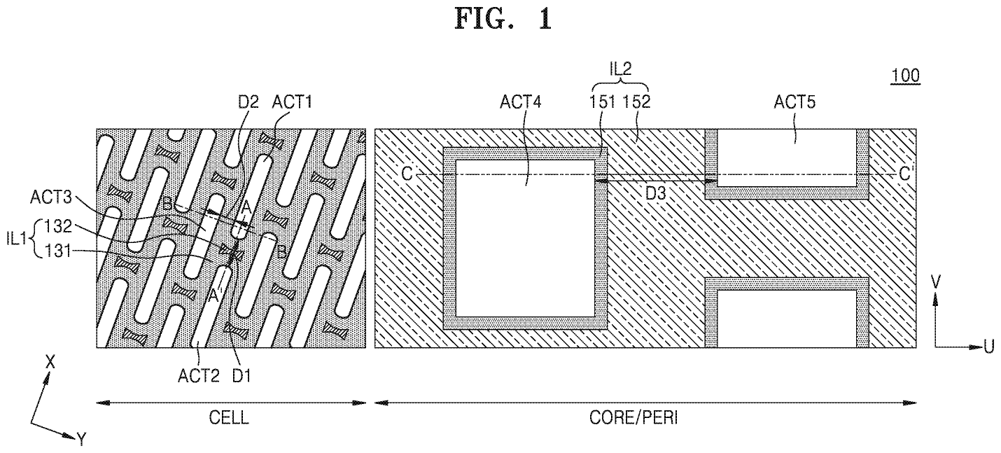

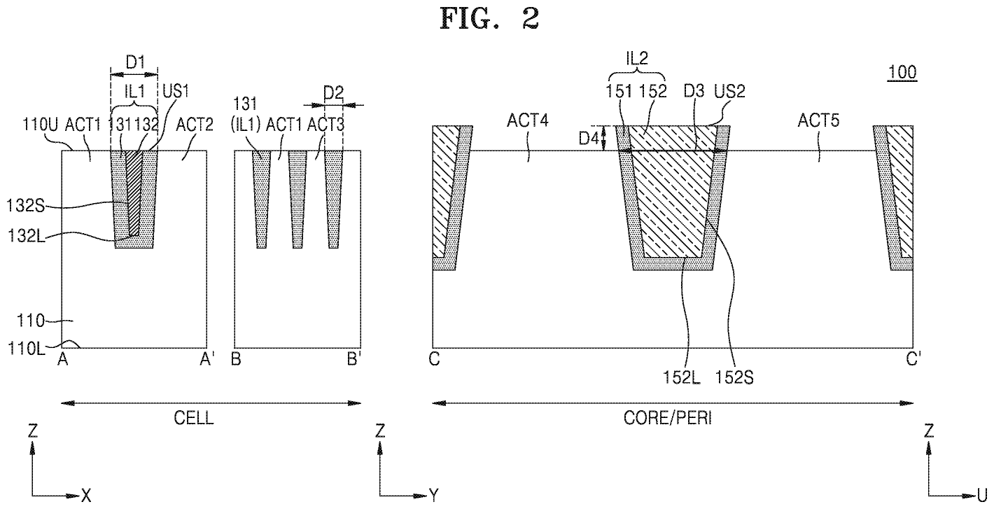

FIG. 1 is a plan view of a semiconductor device 100 according to some embodiments of the inventive concepts. FIG. 2 shows cross-sectional views taken along lines AA′, BB′, and CC′ of FIG. 1.

Referring to FIGS. 1 and 2, the semiconductor device 100 according to some embodiments of the inventive concepts may include a first active region 110 having a cell region CELL and a core/peripheral region CORE/PERI, at least one active region (for example, first through third active regions ACT1, ACT2, and ACT3) in the cell region CELL, a first device isolation layer IL1 in the cell region CELL, at least one active region (for example, fourth and fifth active regions ACT4 and ACT5) in the core/peripheral region CORE/PERI, and a second device isolation layer IL2 in the core/peripheral region CORE/PERI.

The substrate 110 may be a bulk wafer or an epitaxial layer. Also, the substrate 110 may include a semiconductor material, for example, a Group IV semiconductor material, a group III-V semiconductor material, a group II-VI semiconductor material, or a combination of these materials. The group IV semiconductor material may include, for example, Si, Ge, or a combination of these materials. The group III-V semiconductor material may include, for example, GaAs, InP, GaP, InAs, InSb, InGaAs, or a combination of these materials. The group II-VI semiconductor material may include, for example, ZnTe, CdS, or a combination of these materials.

The substrate 110 may have a lower surface 110L and an upper surface 110U that is separated from the lower surface 110L in a first direction (Z-direction). The lower surface 110L of the substrate 110 may be flat and perpendicular to the first direction (Z-direction). In the present specification, the term a “height” of an object may denote a height of the object from the lower surface 110L of the substrate 110 to the object in the first direction (Z-direction) that is perpendicular to the lower surface 110L of the substrate 110. For example, a height of an upper end of the first device isolation layer IL1 may denote a height from the lower surface 110L of the substrate 110 to the upper end of the first device isolation layer IL1 in the first direction (Z-direction). At least one active region (for example, the first through third active regions ACT1, ACT2, or ACT3) in the cell region CELL, the first device isolation layer IL1 in the cell region CELL, at least one active region (for example, the fourth and fifth active regions ACT4 and ACT5) in the core/peripheral region CORE/PERI, and the second device isolation layer IL2 in the core/peripheral region CORE/PERI may be arranged on an upper part of the substrate 110 including the upper surface 110U of the substrate 110.

At least one active region (for example, the first, second, or third active regions ACT1, ACT2, or ACT3) may be defined by the first device isolation layer IL1 in the cell region CELL of the substrate 110. For example, the first through third active regions ACT1 through ACT3 may be defined by the first device isolation layer IL1. However, the number of active regions defined by the first device isolation layer IL1 in the cell region CELL is not limited to the three active regions, and a greater or less number of active regions may be defined. Each of the first through third active regions ACT1, ACT2, and ACT3 in the cell region CELL may have a cross-sectional shape elongated perpendicular to the first direction (Z-direction). For example, the cross-section of each of the first through third active regions ACT1, ACT2, and ACT3 perpendicular to the first direction (Z-direction) may have a major axis in a second direction (X-direction) and a minor axis in a third direction (Y-direction). A plurality of active regions including the first through third active regions ACT1, ACT2, and ACT3 may be repeatedly arranged in the second direction (X-direction) and the third direction (Y-direction) by being spaced apart from each other. For example, the first active region ACT1 and the second active region ACT2 may be spaced apart by a first distance D1 in the second direction (X-direction), that is, in the major axis direction. The first active region ACT1 and the third active region ACT3 may be spaced apart by a second distance D2 in the third direction (Y-direction), that is, in the minor axis direction. The second distance D2 between the first active region ACT1 and the third active region ACT3 may be less than the first distance D1 between the first active region ACT1 and the second active region ACT2.

The first device isolation layer IL1 may include a first insulating film 131 and a second insulating film 132. The first insulating film 131 may contact the first active region ACT1, the second active region ACT2, and the third active region ACT3. The second insulating film 132 may not contact the first active region ACT1, the second active region ACT2, and the third active region ACT3. The second insulating film 132 may contact the first insulating film 131 and may be surrounded by the first insulating film 131. In detail, sidewalls 132S and a lower surface 132L of the second insulating film 132 may be surrounded by the first insulating film 131. The second insulating film 132 may completely fill a space surrounded by the first insulating film 131. The second insulating film 132 may be arranged between two active regions spaced apart in the second direction (X-direction), that is, in the major axis direction, for example, between the first active region ACT1 and the second active region ACT2. However, the second insulating film 132 may not be arranged between two active regions spaced apart in the third direction (Y-direction), that is, in the minor axis direction, for example, between the first active region ACT1 and the third active region ACT3.

In the core/peripheral region CORE/PERI of the substrate 110, at least one active region (for example, the fourth and fifth active regions ACT4 and ACT5) may be defined by the second device isolation layer IL2. For example, the fourth active region ACT4 and the fifth active region ACT5 may be defined by the second device isolation layer IL2. However, the number of active regions defined by the second device isolation layer IL2 in the core/peripheral region CORE/PERI is not limited to the two active regions, and a greater or less number of active regions may be defined. In some embodiments, each of the fourth and fifth active regions ACT4 and ACT5 in the core/peripheral region CORE/PERI may have a cross-section that has approximately a rectangular shape and is perpendicular to the first direction (Z-direction). For example, each of the fourth and fifth active regions ACT4 and ACT5 may have a cross-section that has approximately a rectangular shape having two sides parallel to each other in a fourth direction (U-direction) and two sides parallel to each other in a fifth direction (V-direction) and is perpendicular to the first direction (Z-direction). In some embodiments, the fourth direction (U-direction) and the fifth direction (V-direction) may not be parallel to the second direction (X-direction) and the third direction (Y-direction). However, the shape of the cross-section perpendicular to the first direction (Z-direction) of each of the fourth active region ACT4 and the fifth active region ACT5 in the core/peripheral region CORE/PERI is not limited to the shape of FIG. 2, and may be modified in various ways. The fourth active region ACT4 and the fifth active region ACT5 may be spaced apart by a third distance D3 in the fourth direction (U-direction). The third distance D3 between the fourth active region ACT4 and the fifth active region ACT5 may be greater than the first distance D1 between the first active region ACT1 and the second active region ACT2.

The second device isolation layer IL2 may include a third insulating film 151 and a fourth insulating film 152. The third insulating film 151 may contact the fourth active region ACT4 and the fifth active region ACT5. The fourth insulating film 152 may not contact the fourth active region ACT4 and the fifth active region ACT5. The fourth insulating film 152 may contact the third insulating film 151 and may be surrounded by the third insulating film 151. In detail, sidewalls 152S and a lower surface 152L of the fourth insulating film 152 may contact the third insulating film 151 and be surrounded by the third insulating film 151. The fourth insulating film 152 may completely fill a space surrounded by the third insulating film 151.

In some embodiments, the third insulating film 151 and the fourth insulating film 152 may include the same material. For example, the third insulating film 151 and the fourth insulating film 152 may include a silicon oxide. The first insulating film 131 of the first device isolation layer IL1 may include the same material as the third insulating film 151 and the fourth insulating film 152 of the second device isolation layer IL2. For example, the first insulating film 131 of the first device isolation layer IL1 and the third insulating film 151 and the fourth insulating film 152 of the second device isolation layer IL2 may include a silicon oxide. The second insulating film 132 of the first device isolation layer IL1 may include a different material from the third insulating film 151 and the fourth insulating film 152 of the second device isolation layer IL2. For example, the second insulating film 132 may include a silicon nitride.

When the second device isolation layer IL2 of the core/peripheral region CORE/PERI is filled with the third and fourth insulating films 151 and 152 including a silicon oxide without a silicon nitride film, a hot electron induced punch through (HEIP) may be repressed. Accordingly, the semiconductor device according to some embodiments of the inventive concepts may have higher electrical characteristics. Also, since a silicon nitride film is not present between the third insulating film 151 and the fourth insulating film 152 of the second device isolation layer IL2, the distance D3 between the fourth active region ACT4 and the fifth active region ACT5 may be reduced. Accordingly, an area of the core/peripheral region CORE/PERI in the substrate 110 may be reduced.

In the present specification, for convenience of explanation, the term “the n^{th}” (n is a natural number), such as “the first” and “the second” is used only to distinguish a constituent element from another constituent element having the same name. Accordingly, according to the sequence of description, the fourth active region ACT4 in the core/peripheral region CORE/PERI may be referred to as a second active region. Also, the third insulating film 151 and the fourth insulating film 152 included in the second device isolation layer IL2 in the core/peripheral region CORE/PERI may be referred to as a first insulating film and a second insulating film.

At least a portion of an upper surface US2 of the second device isolation layer IL2 may protrude in the first direction (Z-direction), that is, an upward direction by as much as a fourth distance D4 from the fourth active region ACT4 and the fifth active region ACT5. That is, a height of an upper end of the second device isolation layer IL2 may be greater than a height of upper ends of the fourth active region ACT4 and the fifth active region ACT5. Here, the upper ends of the fourth active region ACT4 and the fifth active region ACT5 may denote a higher point of the upper ends of the fourth active region ACT4 and the fifth active region ACT5. The fourth distance D4 formed by protruding the at least a portion of the upper surface US2 of the second device isolation layer IL2 from the upper ends of the fourth active region ACT4 and the fifth active region ACT5 in the first direction (Z-direction) may be less than the third distance D3 between the fourth active region ACT4 and the fifth active region ACT5. The fourth distance D4 may be, for example, in a range of about 10 Å to about 200 Å. In some embodiments, at least a portion of the third insulating film 151 and at least a portion of the fourth insulating film 152 may upwardly protrude from the fourth active region ACT4 and the fifth active region ACT5. That is, the height of the upper portion of the third insulating film 151 and the height of the upper portion of fourth insulating film 152 may be greater than the height of the upper ends of the fourth active region ACT4 and the fifth active region ACT5.

However, an upper surface US1 of the first device isolation layer IL1 in the cell region CELL may not upwardly protrude from the first through third active regions ACT1, ACT2, and ACT3. That is, a height of an upper end of the first device isolation layer IL1 may be less than or equal to a height of upper ends of the first through third active regions ACT1, ACT2, and ACT3.

In some embodiments, the height of the upper ends of the first through third active regions ACT1, ACT2, and ACT3 in the cell region CELL may be less than or equal to the height of the upper ends of the fourth active region ACT4 and the fifth active region ACT5 in the core/peripheral region CORE/PERI. Also, the height of the upper end of the first device isolation layer IL1 in the cell region CELL may be less than the height of the upper end of the second device isolation layer IL2 in the core/peripheral region CORE/PERI.

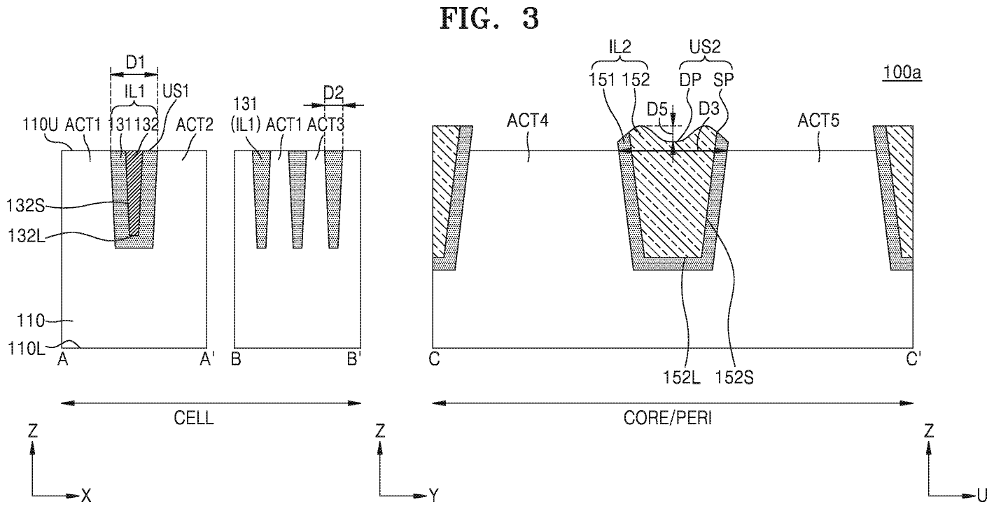

FIG. 3 shows cross-sectional views of a semiconductor device 100a according to some embodiments of the inventive concepts. Hereinafter, differences between the semiconductor device 100 of FIG. 2 and the semiconductor device 100a of FIG. 3 will be described.

Referring to FIG. 3, the upper surface US2 of the second device isolation layer IL2 may include a dent DP having a shape depressed in a direction opposite to the first direction (Z-direction), that is, a downward direction. In some embodiments, the upper surface US2 of the second device isolation layer IL2 may further include a sloped portion SP. The sloped portion SP may be located between the fourth active region ACT4 and the dent DP and between the fifth active region ACT5 and the dent DP, and may be inclined towards the dent DP with respect to the first direction (Z-direction). In some embodiments, a depth D5 of the dent DP depressed in a direction opposite to the first direction (Z-direction), that is, the downward direction, may be less than the third distance D3 between the fourth active region ACT4 and the fifth active region ACT5. The depth D5 of the dent DP depressed in the direction opposite to the first direction (Z-direction) may be in a range of about 10 Å to about 200 Å.

In some embodiments, the whole upper surface US2 of the second device isolation layer IL2 may protrude from the fourth active region ACT4 and the fifth active region ACT5. That is, a height of a lower end of the dent DP of the upper surface US2 of the second device isolation layer IL2 may be greater than the height of the upper ends of the fourth active region ACT4 and the fifth active region ACT5.

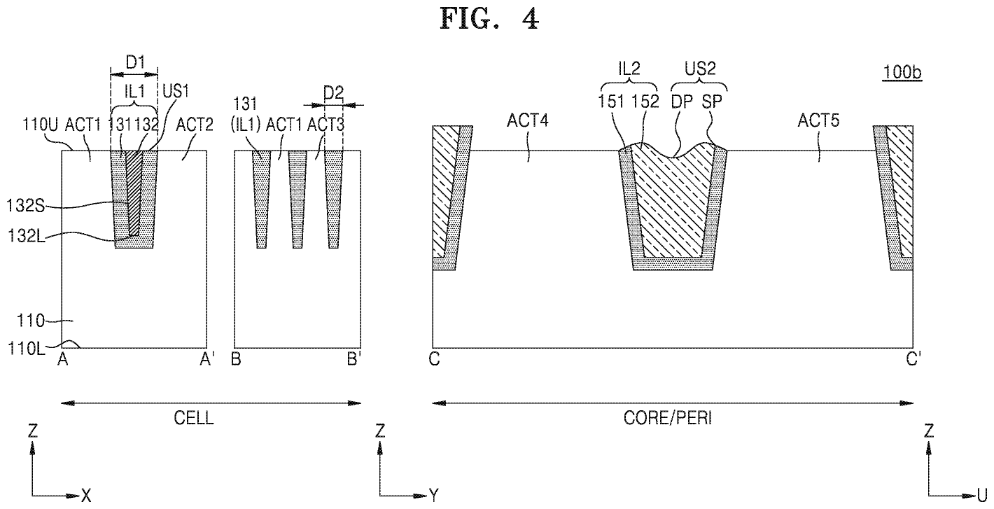

FIG. 4 shows cross-sectional views of a semiconductor device 100b according to some embodiments of the inventive concepts. Hereinafter, differences between the semiconductor device 100a of FIG. 3 and the semiconductor device 100b of FIG. 4 will be described.

In some embodiments, only a portion of the upper surface US2 of the second device isolation layer IL2 may protrude from the fourth active region ACT4 and the fifth active region ACT5. That is, the portion of the upper surface US2 of the second device isolation layer IL2 may not protrude from the fourth active region ACT4 and the fifth active region ACT5. That is, the height of a lower end of the dent DP of the upper surface US2 of the second device isolation layer IL2 may be less than the height of the upper ends of the fourth active region ACT4 and the fifth active region ACT5.

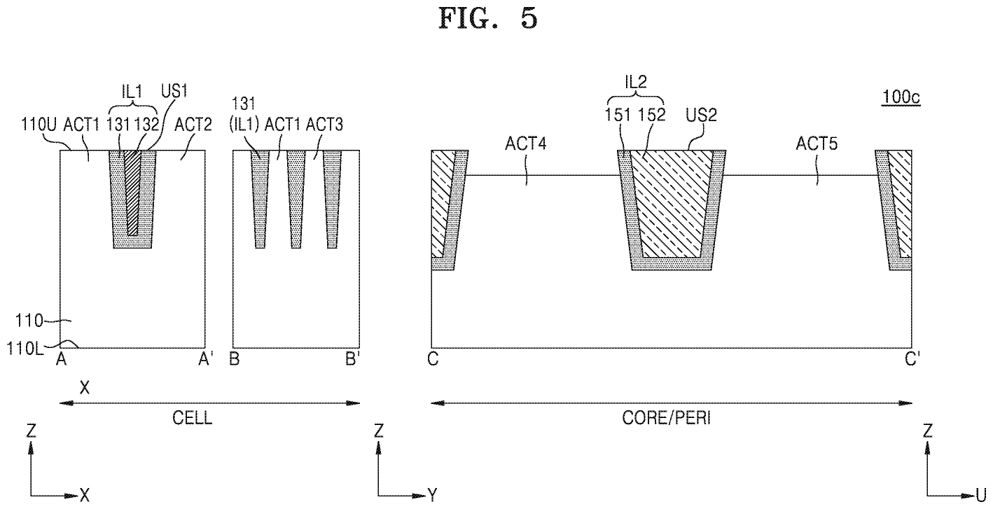

FIG. 5 shows cross-sectional views of a semiconductor device 100c according to some embodiments of the inventive concepts. Hereinafter, differences between the semiconductor device 100 of FIG. 2 and the semiconductor device 100c of FIG. 5 will be described.

Referring to FIG. 5, the height of the upper ends of the first active region ACT1, the second active region ACT2, and the third active region ACT3 of the cell region CELL may be greater than the height of the upper ends of the fourth active region ACT4 and the fifth active region ACT5 of the core/peripheral region CORE/PERI. Also, in some embodiments, the height of the first device isolation layer IL1 of the cell region CELL may be greater or equal to the upper end of the second device isolation layer IL2 of the core/peripheral region CORE/PERI.

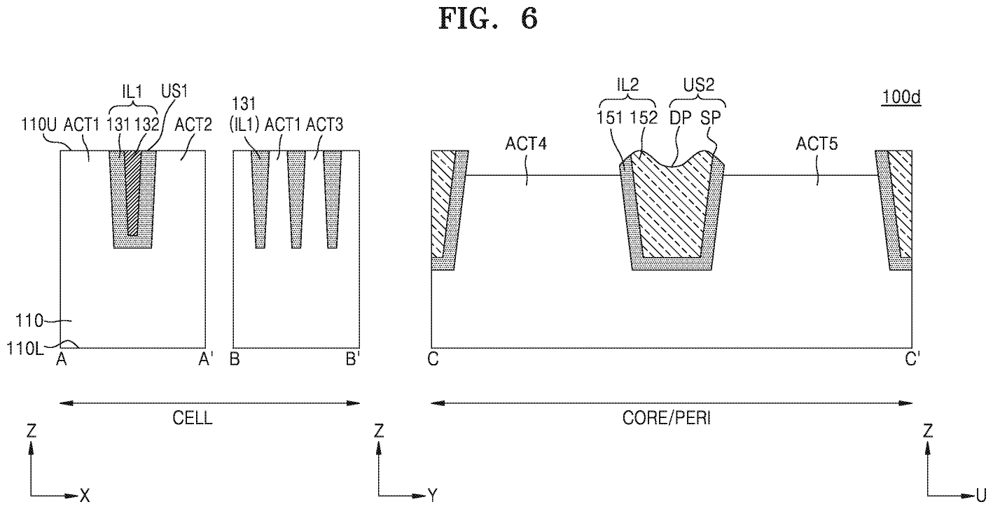

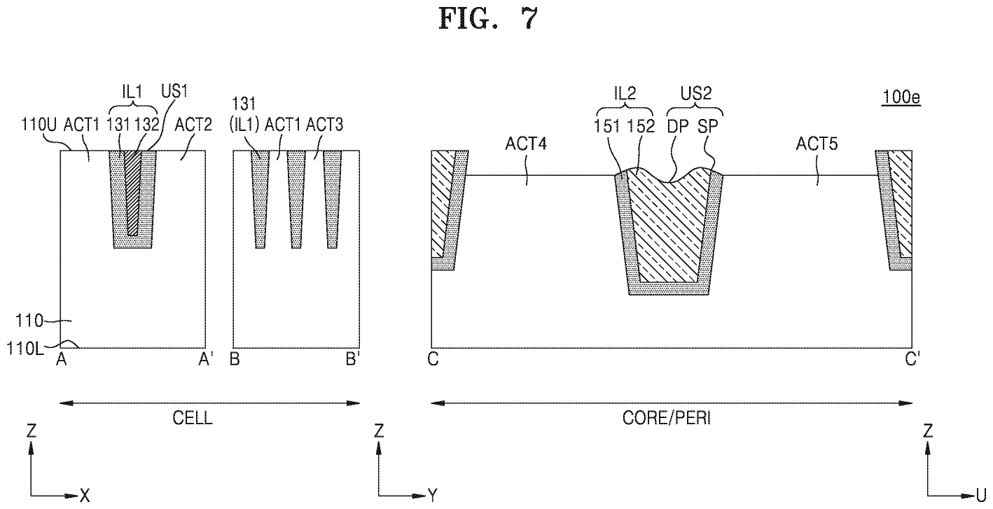

FIGS. 6 and 7 are cross-sectional views of semiconductor devices 100d and 100e according to some embodiments of the inventive concepts. Hereinafter, differences between the semiconductor device 100c of FIG. 5 and the semiconductor devices 100d and 100e of FIGS. 6 and 7 will be described.

Referring to FIGS. 6 and 7, the upper surface US2 of the second device isolation layer IL2 may include the dent DP depressed in a direction opposite to the first direction (Z-direction), that is, in a downward direction. The upper surface US2 of the second device isolation layer IL2 may additionally include the sloped portion SP. Detailed descriptions about the dent DP and the sloped portion SP are made above with reference to FIGS. 3 and 4.

In some embodiments, as depicted in FIG. 6, the whole upper surface US2 of the second device isolation layer IL2 may protrude from the fourth active region ACT4 and the fifth active region ACT5. In some other embodiments, as depicted in FIG. 7, only a portion of the upper surface US2 of the second device isolation layer IL2 may protrude from the fourth active region ACT4 and the fifth active region ACT5.

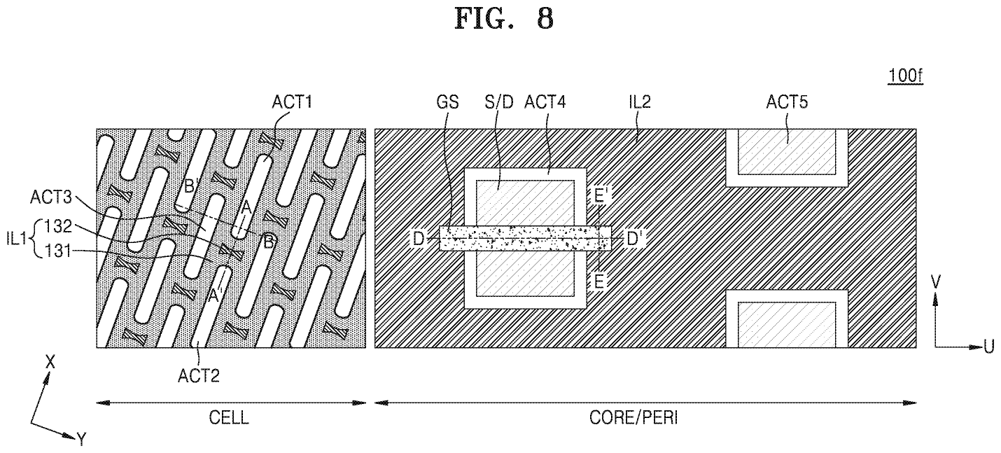

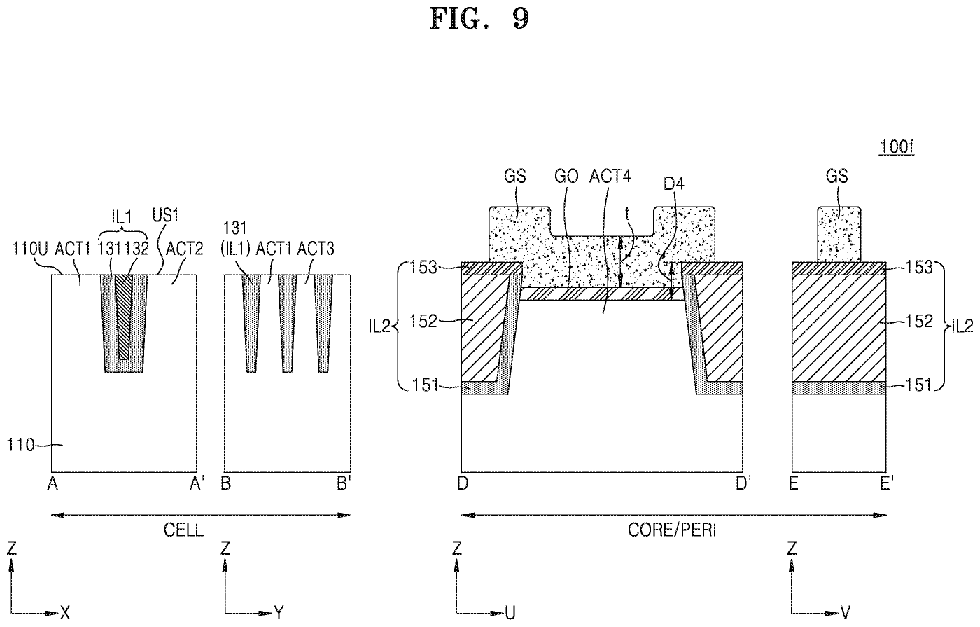

FIG. 8 is a plan view of a semiconductor device 100f according to some embodiments of the inventive concepts. FIG. 9 shows cross-sectional views taken along lines AA′, BB″, DD′, and EE′ of FIG. 8. Hereinafter, differences between the semiconductor device 100c of FIG. 5 and the semiconductor device 100f of FIGS. 8 and 9 will be described.

Referring to FIGS. 8 and 9, the second device isolation layer IL2 may further include a capping insulating film 153 besides the third insulating film 151 and the fourth insulating film 152. The capping insulating film 153 may cover an upper surface of the fourth insulating film 152. In some embodiments, the capping insulating film 153 may also cover an upper surface of the third insulating film 151. The capping insulating film 153 may contact the third insulating film 151 and the fourth insulating film 152. Also, the capping insulating film 153 may be separated from the fourth active region ACT4. In some embodiments, the capping insulating film 153 may include the same material, for example, a silicon nitride, as the second insulating film 132 of the first device isolation layer IL1.

In some embodiments, the semiconductor device 100f may further include a gate insulating film GO, a gate structure GS, and/or a source/drain region S/D. The gate insulating film GO may be arranged on the fourth active region ACT4. The gate structure GS may be arranged on the gate insulating film GO and may extend to the upper end of the second device isolation layer IL2. The gate structure GS may include, for example, polysilicon. The source/drain region S/D may be arranged in the fourth active region ACT4 of both sides of the gate structure GS.

The gate structure GS may contact the third insulating film 151 and the capping insulating film 153 of the second device isolation layer IL2. The gate structure GS may be separated from the fourth insulating film 152 of the second device isolation layer IL2. In some embodiments, a thickness t of the gate structure GS in the first direction (Z-direction) may be greater than the fourth distance D4, which is a distance from the upper end of the fourth active region ACT4 to the upper end of the second device isolation layer IL2 in the first direction (Z-direction). For example, the thickness t of the gate structure GS in the first direction (Z-direction) may be in a range of about 200 Å to about 400 Å, and the fourth distance D4 from the upper end of the fourth active region ACT4 to the upper end of the second device isolation layer IL2 in the first direction (Z-direction) may be in a range of about 10 Å to about 200 Å.

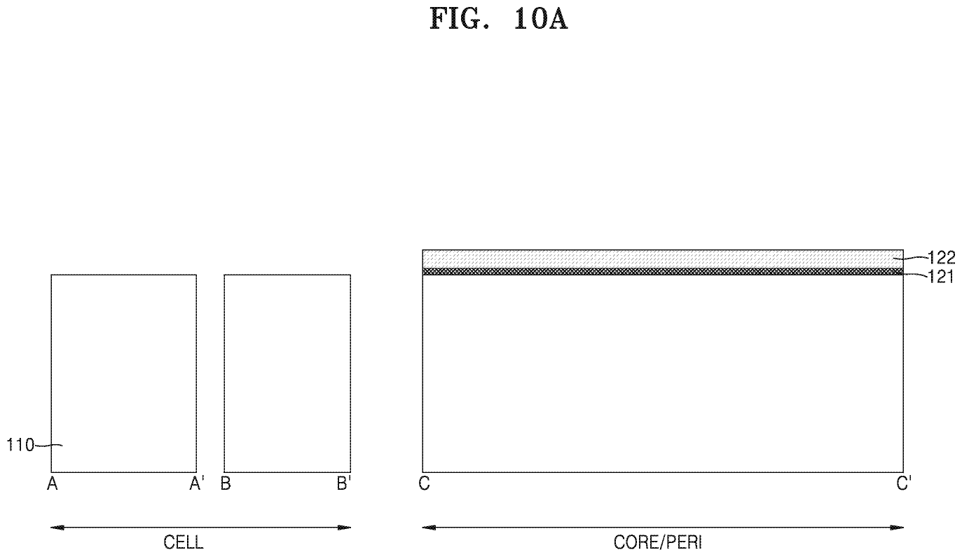

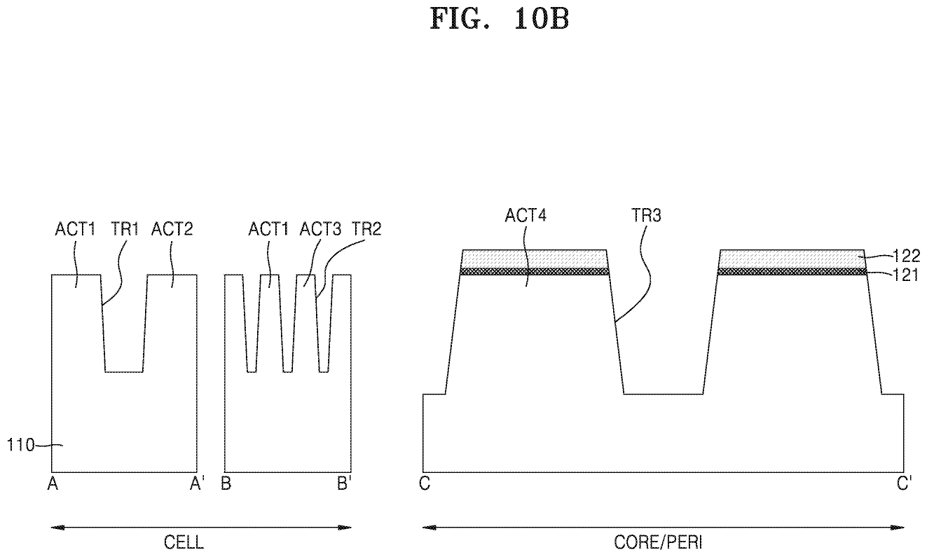

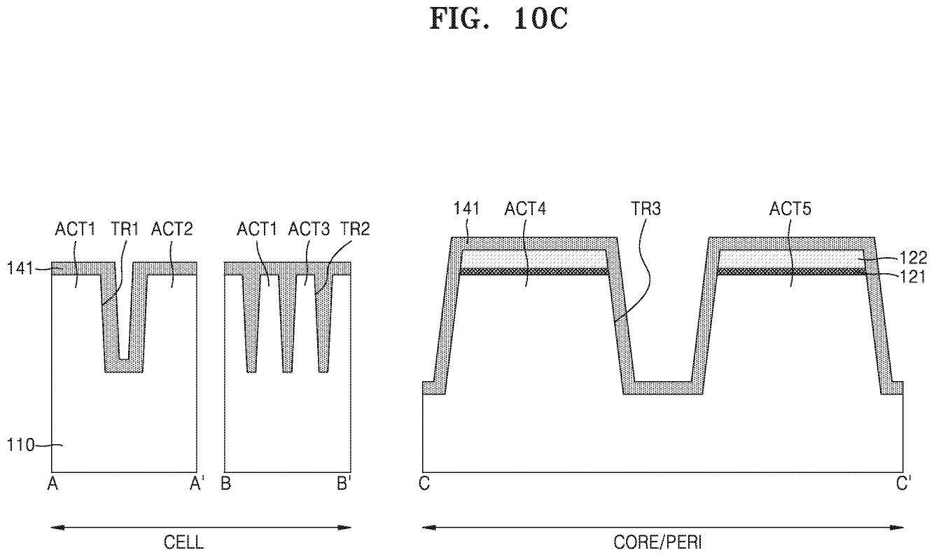

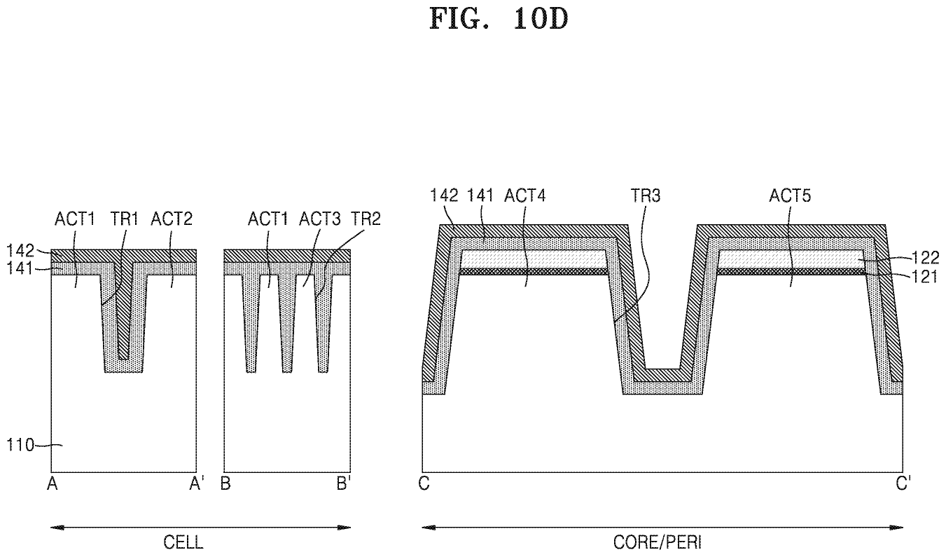

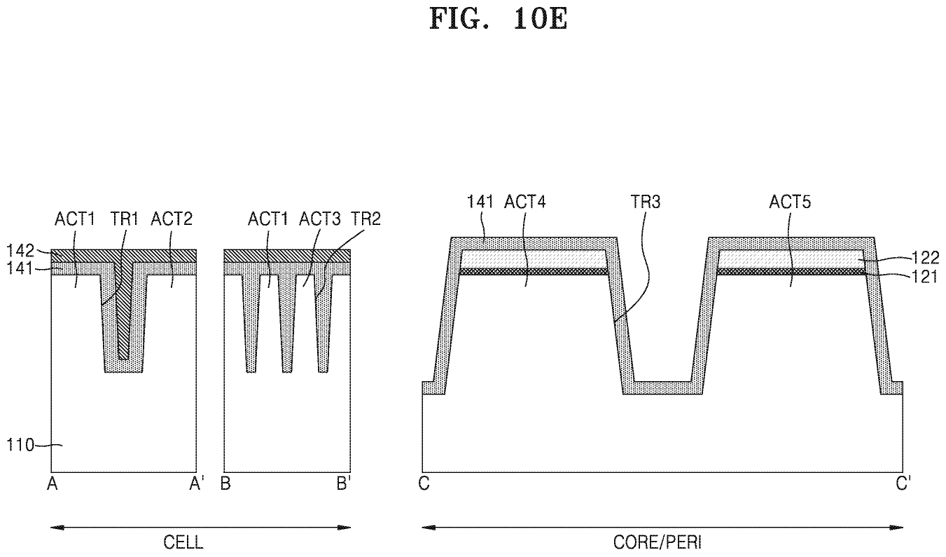

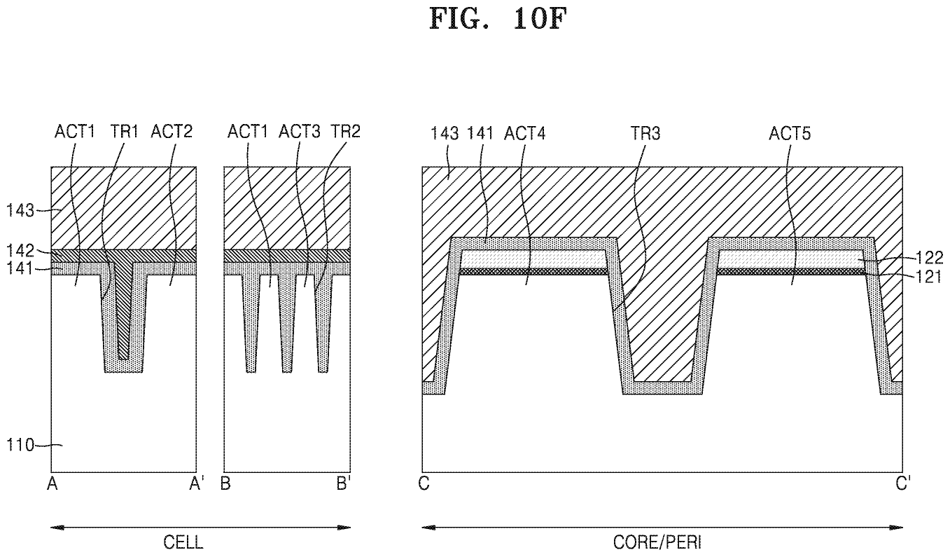

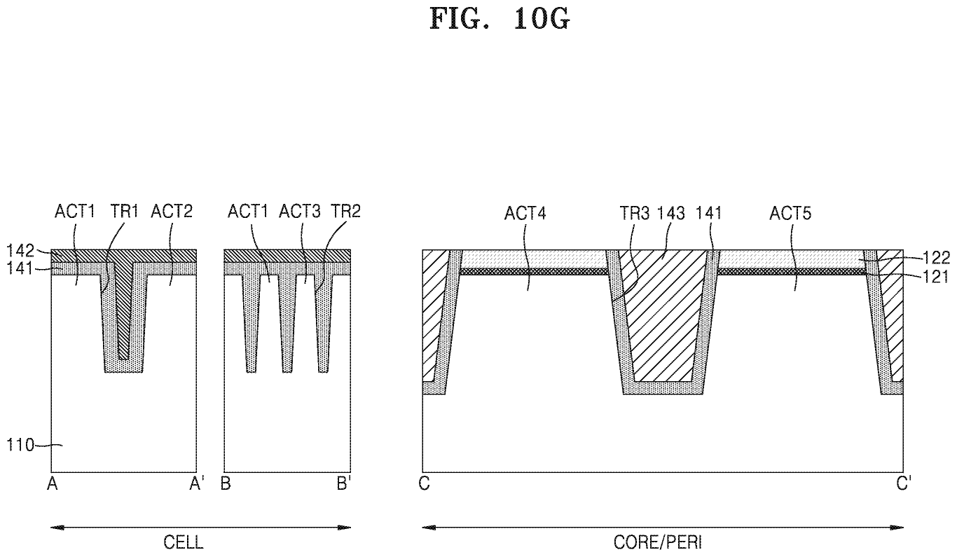

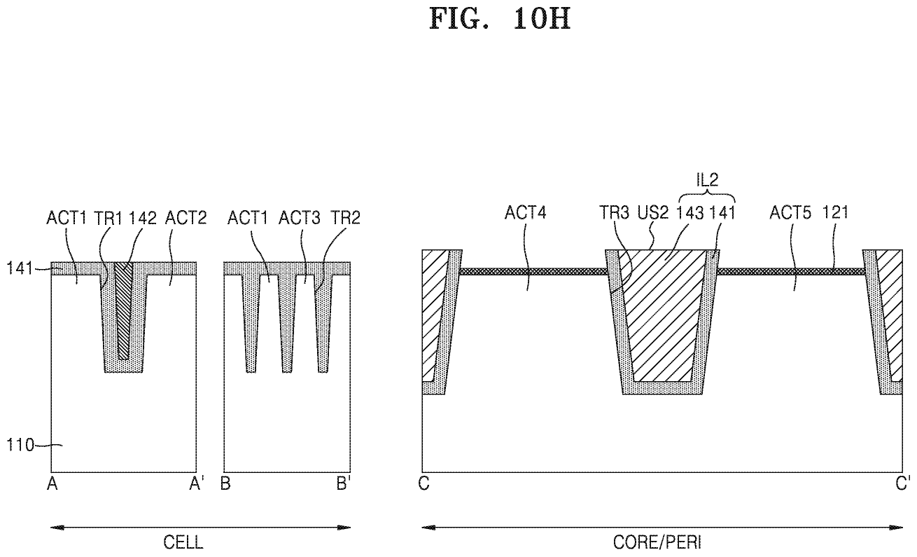

FIGS. 10A through 10H are cross-sectional views of a method of manufacturing a semiconductor device, according to some embodiments of the inventive concepts.

Referring to FIG. 10A, a pad oxide film 121 and a raised nitride film 122 may be formed on the substrate 110. The pad oxide film 121 may be formed by using, for example, a thermal oxidation method, an atomic layer deposition (ALD) method, or a combination of these methods. The raised nitride film 122 may be formed by using a deposition method, such as an ALD method, a chemical vapor deposition (CVD) method, or a plasma enhanced chemical vapor deposition (PECVD) method. Afterwards, the pad oxide film 121 and the raised nitride film 122 formed on the cell region CELL of the substrate 110 may be removed by using a photolithography process and/or an etching process. Accordingly, the pad oxide film 121 and the raised nitride film 122 may remain only on the core/peripheral region CORE/PERI of the substrate 110.

Referring to FIG. 10B, a plurality of trenches TR1, TR2, and TR3 may be formed in the cell region CELL and the core/peripheral region CORE/PERI of the substrate 110. The plurality of trenches TR1, TR2, and TR3 may be formed by a photolithography process and/or an etching process.

Referring to FIG. 10C, a first oxide film 141 may be deposited. The first oxide film 141 may be deposited by using, for example, a thermal oxidation method, an ALD method, a CVD method, a PECVD method, or a combination of these methods. The first oxide film 141 in the cell region CELL may cover upper surfaces of the first through third active regions ACT1, ACT2, and ACT3. The first oxide film 141 in the cell region CELL may not completely fill the trench TR1 between the first active region ACT1 and the second active region ACT2. However, the first oxide film 141 in the cell region CELL may completely fill the trench TR2 between the first active region ACT1 and the third active region ACT3. The first oxide film 141 in the core/peripheral region CORE/PERI may not completely fill the trench TR3 between the fourth active region ACT4 and the fifth active region ACT5. In some embodiments, a thin polysilicon film may be formed before depositing the first oxide film 141.

Referring to FIG. 10D, a first nitride film 142 may be deposited on the first oxide film 141. The first nitride film 142 may be deposited by using, for example, an ALD method, a CVD method, a PECVD method, or a combination of these methods. The first nitride film 142 in the cell region CELL may completely fill the trench TR1 between the first active region ACT1 and the second active region ACT2. However, the first nitride film 142 in the core/peripheral region CORE/PERI may not completely fill the trench TR3 between the fourth active region ACT4 and the fifth active region ACT5.

Referring to FIG. 10E, the first nitride film 142 in the core/peripheral region CORE/PERI may be removed. The first nitride film 142 may remain only in the cell region CELL by etching the first nitride film 142 on the core/peripheral region CORE/PERI after forming a mask on the first nitride film 142 in the cell region CELL by using, for example, a photolithography process.

Referring to FIG. 10F, a second oxide film 143 may be formed. The second oxide film 143 may cover the first nitride film 142 in the cell region CELL and the first oxide film 141 in the core/peripheral region CORE/PERI. The second oxide film 143 may completely fill the trench TR3 in the core/peripheral region CORE/PERI. The second oxide film 143 may be formed by heat treating a fluid-state material after coating the fluid-state material, for example, tenon silazene (TOSZ). In some embodiments, a thin polysilicon film may be formed before forming the second oxide film 143.

Referring to FIGS. 10G and 10H, the second oxide film 143 may be polished by, for example, a chemical mechanical polishing (CMP) method. The second oxide film 143 in the cell region CELL may be polished so that the first nitride film 142 is exposed, and thus, all of the second oxide film 143 in the cell region CELL may be removed. The second oxide film 143 in the core/peripheral region CORE/PERI may be polished so that the raised nitride film 122 is exposed.

Referring to FIG. 10H, the first nitride film 142 in the cell region CELL is removed except for the portion of the first nitride film 142 that fills the trench TR1, and thus, the first oxide film 141 may be exposed. Also, the raised nitride film 122 in the core/peripheral region CORE/PERI is removed, and thus, the pad oxide film 121 may be exposed.

Referring to FIG. 10H and FIG. 2, an upper part of the first oxide film 141 covering the first through third active regions ACT1, ACT2, and ACT3 in the cell region CELL of the substrate 110, an upper part of the first nitride film 142 in the cell region CELL, and the pad oxide film 121 covering the fourth active region ACT4 and the fifth active region ACT5 in the core/peripheral region CORE/PERI may be removed. Thus, the first device isolation layer IL1 and the second device isolation layer IL2 that are depicted in FIG. 2 may be formed. That is, the first oxide film 141 and the first nitride film 142 in the cell region CELL of FIG. 10H may form the first insulating film 131 and the second insulating film 132 respectively of the first device isolation layer IL1 in the cell region CELL of FIG. 2. Also, the first oxide film 141 and the second oxide film 143 in the core/peripheral region CORE/PERI of FIG. 10H may form the third insulating film 151 and the fourth insulating film 152 respectively of the second device isolation layer IL2 in the core/peripheral region CORE/PERI of FIG. 2.

Referring to FIG. 10H, FIG. 3, and FIG. 4, in some cases, when the first oxide film 141 and the pad oxide film 121 are removed, a portion of an upper part of the second device isolation layer IL2 may be removed together with the first oxide film 141 and the pad oxide film 121. In these cases, the height of the upper surface US2 of the second device isolation layer IL2 may be reduced or, as depicted in FIGS. 3 and 4, the upper surface US2 of the second device isolation layer IL2 may be changed to a depressed shape. However, before etching the first oxide film 141 and the pad oxide film 121, since the height of the upper surface US2 of the second device isolation layer IL2 is higher than the upper ends of the fourth active region ACT4 and the fifth active region ACT5, although a portion of the second device isolation layer IL2 is etched during the etching of the first oxide film 141 and the pad oxide film 121, as depicted in FIGS. 3 and 4, after etching, at least a portion of the upper surface US2 of the second device isolation layer IL2 may protrude from the fourth active region ACT4 and the fifth active region ACT5. Accordingly, a process margin of removing the first oxide film 141 and the pad oxide film 121 may be increased.

Afterwards, the gate insulating film GO (refer to FIG. 9) may be formed on the fourth active region ACT4 or the fifth active region ACT5, and the gate structure GS (refer to FIG. 9) may be formed on the gate insulating film GO. The gate structure GS may extend to the upper end of the second device isolation layer IL2. At this point, if the height of the upper end of the second device isolation layer IL2 is greater than the height of the upper ends of the fourth active region ACT4 and the fifth active region ACT5, the etching of the gate structure GS may be easier than a case when the height of the upper end of the second device isolation layer IL2 is less than the height of the upper ends of the fourth active region ACT4 and the fifth active region ACT5. Accordingly, a process margin for forming the gate structure GS may be increased.

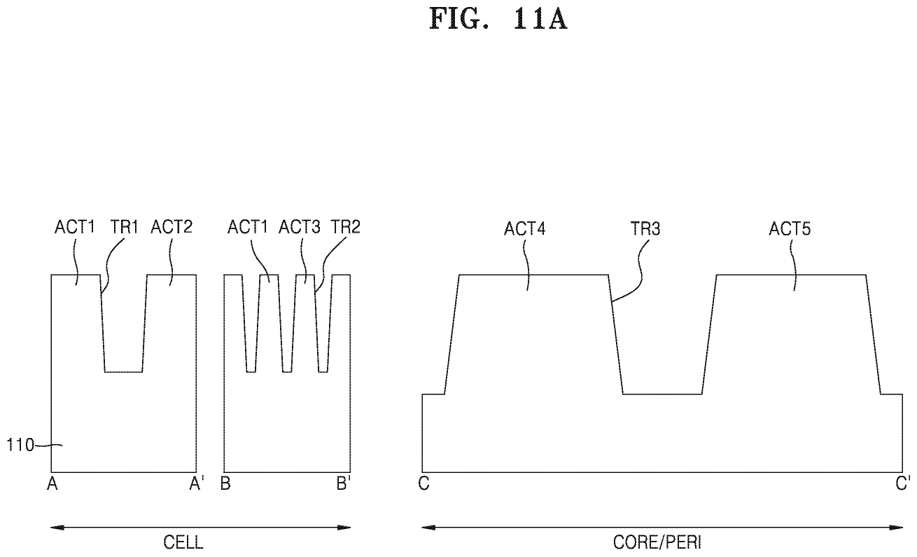

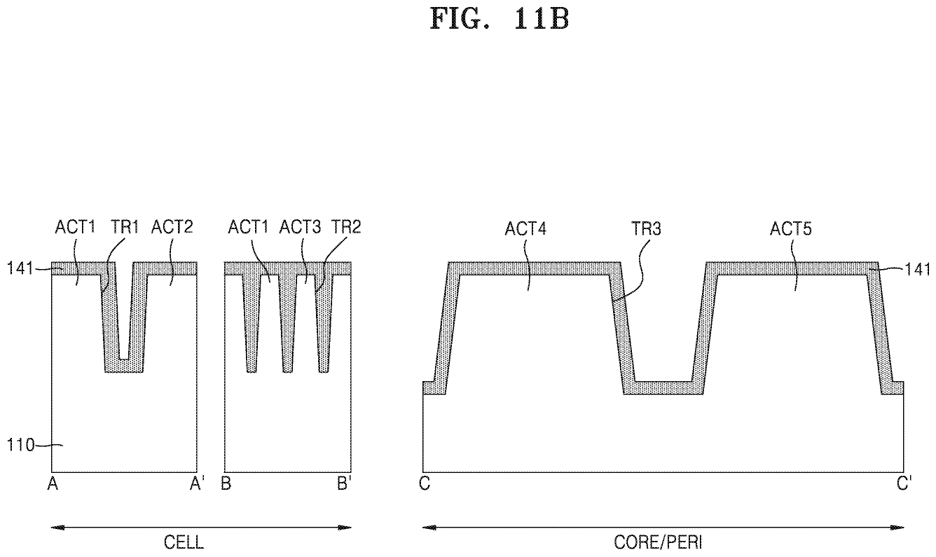

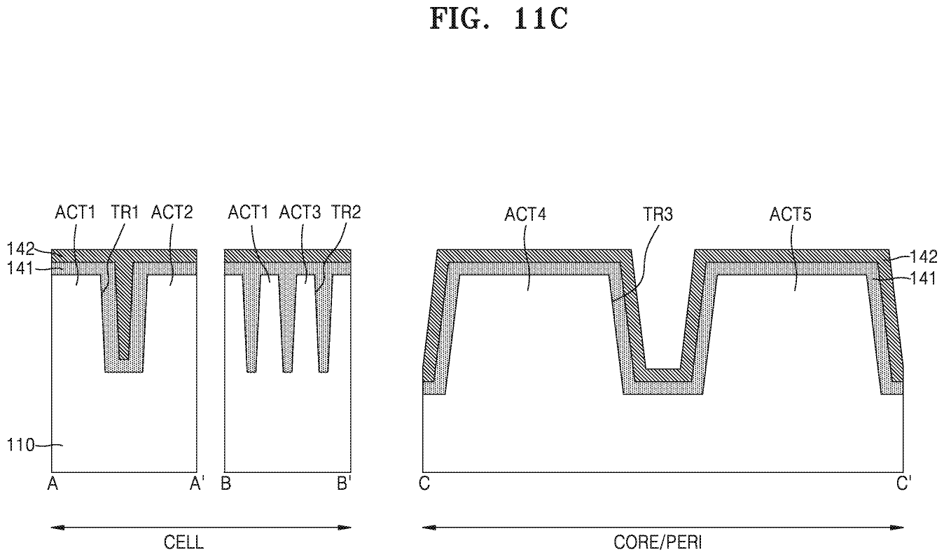

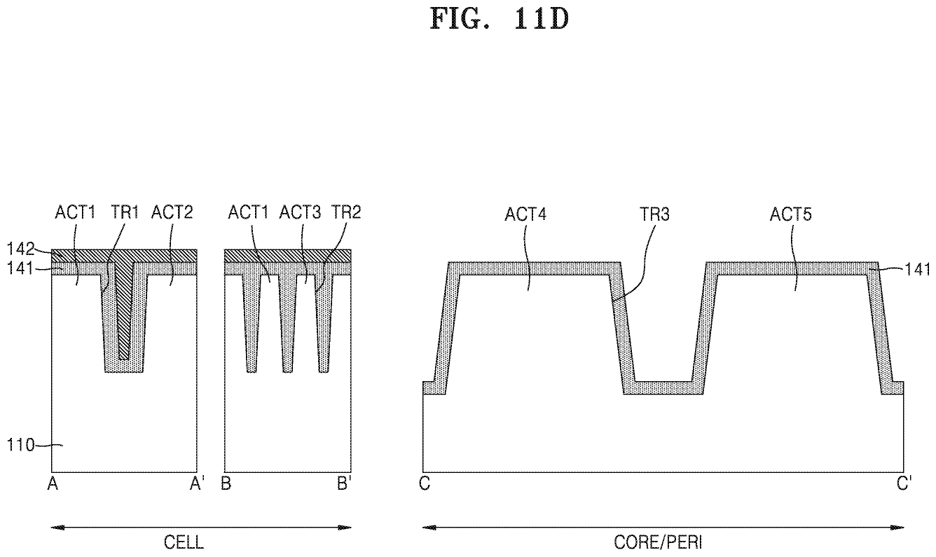

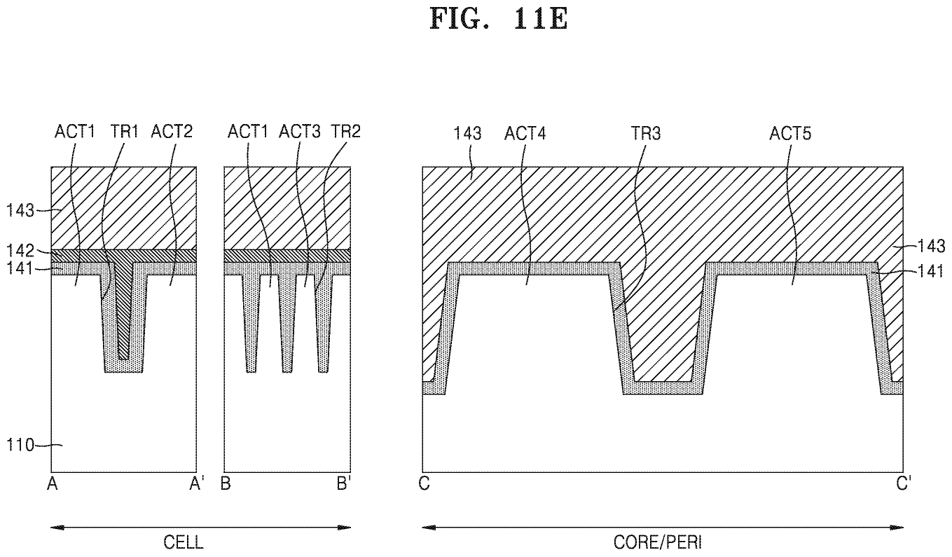

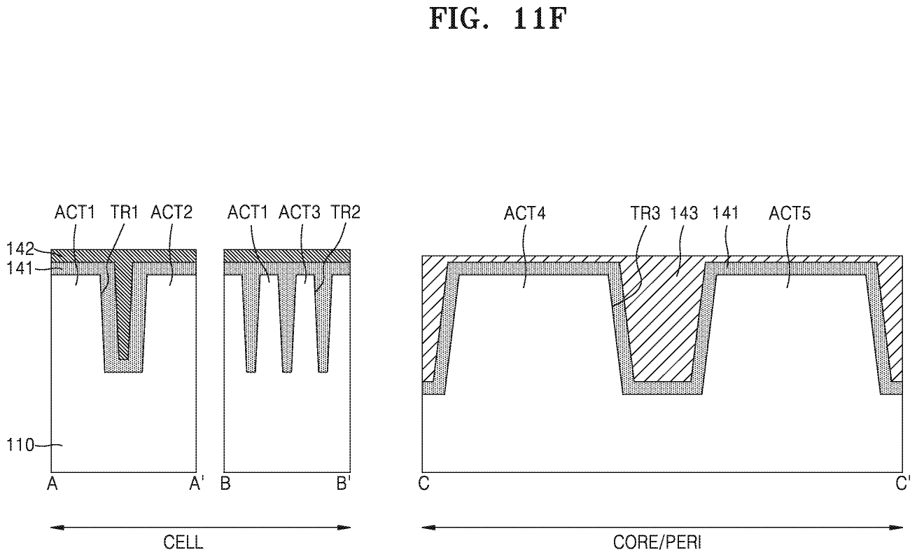

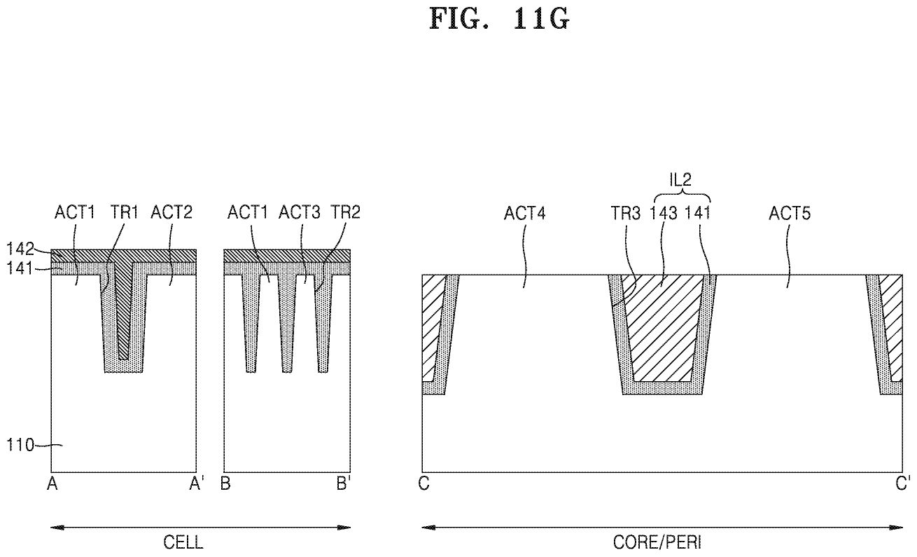

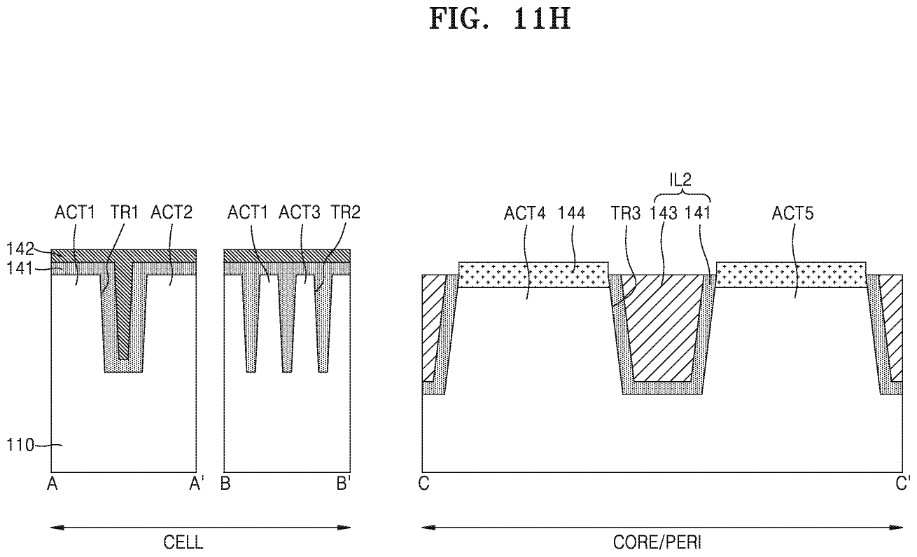

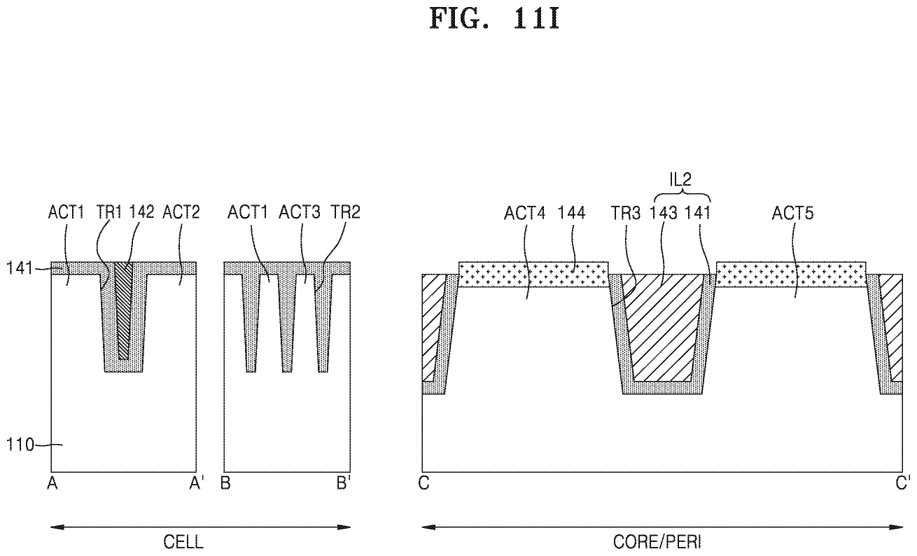

FIGS. 11A through 11I are cross-sectional views of a method of manufacturing a semiconductor device, according to some embodiments of the inventive concepts.

Referring to FIG. 11A, trenches TR1, TR2, and TR3 that define the first through fifth active regions ACT1 through ACT5 may be formed in the substrate 110. The trenches TR1, TR2, and TR3 may be formed by using a photolithography process and/or an etching process.

Referring to FIG. 11B, the first oxide film 141 may be formed on the substrate 110. The first insulating film 131 in the cell region CELL may not completely fill the trench TR1 between the first active region ACT1 and the second active region ACT2. However, the first insulating film 131 in the cell region CELL may completely fill the trench TR2 between the first active region ACT1 and the third active region ACT3. Also, the first insulating film 131 in the core/peripheral region CORE/PERI may not completely fill the trench TR3 between the fourth active region ACT4 and the fifth active region ACT5. In some embodiments, a thin silicon film may be formed on the substrate 110 before forming the first oxide film 141.

Referring to FIG. 11C, the first nitride film 142 may be formed on the first oxide film 141. The first nitride film 142 may completely fill the trench TR1 between the first active region ACT1 and the second active region ACT2 of the cell region CELL. However, the first nitride film 142 may not completely fill the trench TR3 between the fourth active region ACT4 and the fifth active region ACT5 of the core/peripheral region CORE/PERI.

Referring to FIG. 11D, the first nitride film 142 in the core/peripheral region CORE/PERI may be removed. Thus, the first nitride film 142 on the core/peripheral region CORE/PERI may be removed and the first nitride film 142 may remain only on the cell region CELL by etching the first nitride film 142 after forming a mask on the first nitride film 142 in the cell region CELL by using, for example, a photolithography process.

Referring to FIG. 11E, the second oxide film 143 may be formed. The second oxide film 143 in the cell region CELL may cover the first nitride film 142. The second oxide film 143 in the core/peripheral region CORE/PERI may cover the first oxide film 141. The second oxide film 143 may completely fill the trench TR3 between the fourth active region ACT4 and the fifth active region ACT5 in the core/peripheral region CORE/PERI.

Referring to FIGS. 11E and 11F, the second oxide film 143 may be polished by, for example, a CMP process. The second oxide film 143 may be polished so that the first nitride film 142 in the cell region CELL is exposed. Thus, all of the second oxide film 143 in the cell region CELL may be removed.

Referring to FIG. 11G, the first oxide film 141 and the second oxide film 143 may be etched so that the fourth active region ACT4 and the fifth active region ACT5 in the core/peripheral region CORE/PERI are exposed. Thus, the second device isolation layer IL2 depicted in FIG. 5 may be formed. That is, the first oxide film 141 and the second oxide film 143 in the core/peripheral region CORE/PERI of FIG. 11G may form the third insulating film 151 and the fourth insulating film 152 of the second device isolation layer IL2 in the core/peripheral region CORE/PERI of FIG. 5.

Referring to FIG. 11H, a third oxide film 144 may be formed by oxidizing the fourth active region ACT4 and the fifth active region ACT5 in the core/peripheral region CORE/PERI. Since the third oxide film 144 is formed, upper surfaces of the fourth and fifth active regions ACT4 and ACT5 may be lowered. Also, a height of an upper end of the third oxide film 144 may be greater than the upper end of the second device isolation layer IL2. While the third oxide film 144 is formed, heat may be applied to the second oxide film 143, and thus, the second oxide film 143 may have an increased etch resistance due to the heat.

Referring to FIGS. 11H and 11I, a portion of the first nitride film 142 in the cell region CELL may be removed.

Referring to FIGS. 11I and 5, next, an upper part of the first oxide film 141 and an upper part of the first nitride film 142 on the cell region CELL and the third oxide film 144 on the core/peripheral region CORE/PERI may be removed. Thus, the first device isolation layer IL1 and the second device isolation layer IL2 depicted in FIG. 5 may be formed. That is, the first oxide film 141 and the first nitride film 142 in the cell region CELL of FIG. 11I may respectively form the first insulating film 131 and the second insulating film 132 of the first device isolation layer IL1 of the cell region CELL of FIG. 5.

Referring to FIGS. 11I, 6, and 7, in some cases, when the first oxide film 141 and the third oxide film 144 are removed, a portion of an upper part of the second device isolation layer IL2 may also be removed together with the first oxide film 141 and the third oxide film 144. In this case, the upper surface US2 of the second device isolation layer IL2 is lowered, or as depicted in FIGS. 6 and 7, the upper surface US2 of the second device isolation layer IL2 may be changed to a depressed shape. A speed of etching the second oxide film 143 may be reduced when the third oxide film 144 is etched due to heat applied to the second oxide film 143 during an oxidation process for forming the third oxide film 144. Accordingly, an amount of etching the upper part of the second device isolation layer IL2 may be reduced, and a depression depth of the upper surface US2 of the second device isolation layer IL2 may be reduced. Accordingly, at least a portion of the upper surface US2 of the second device isolation layer IL2 may be maintained as protruded from the fourth and fifth active regions ACT4 and ACT5.

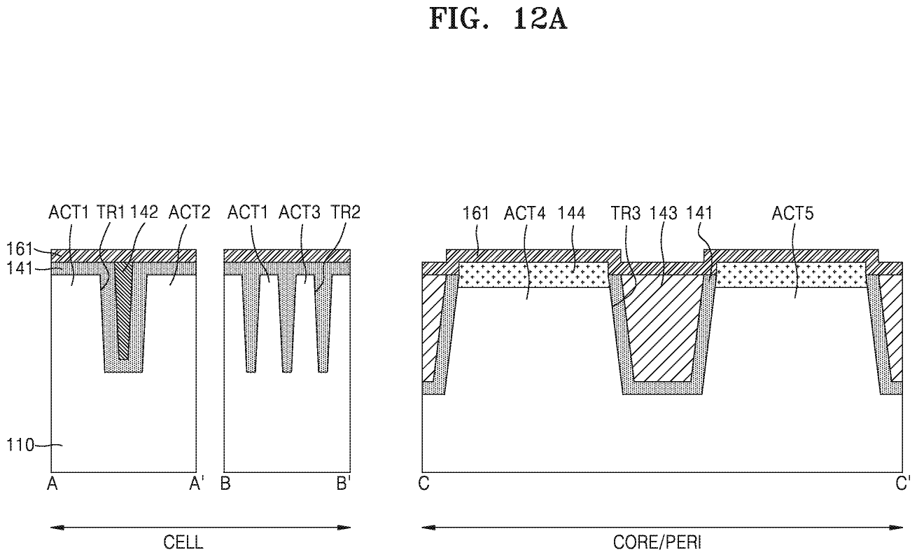

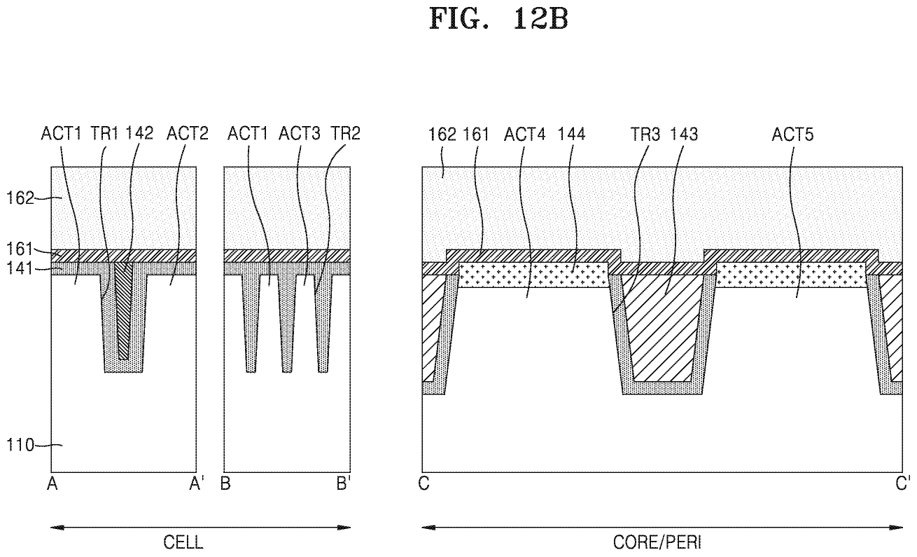

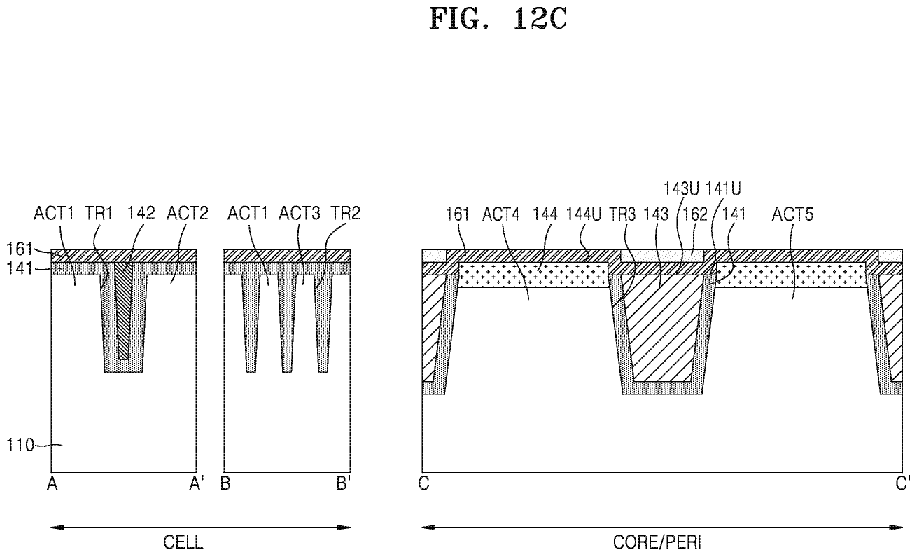

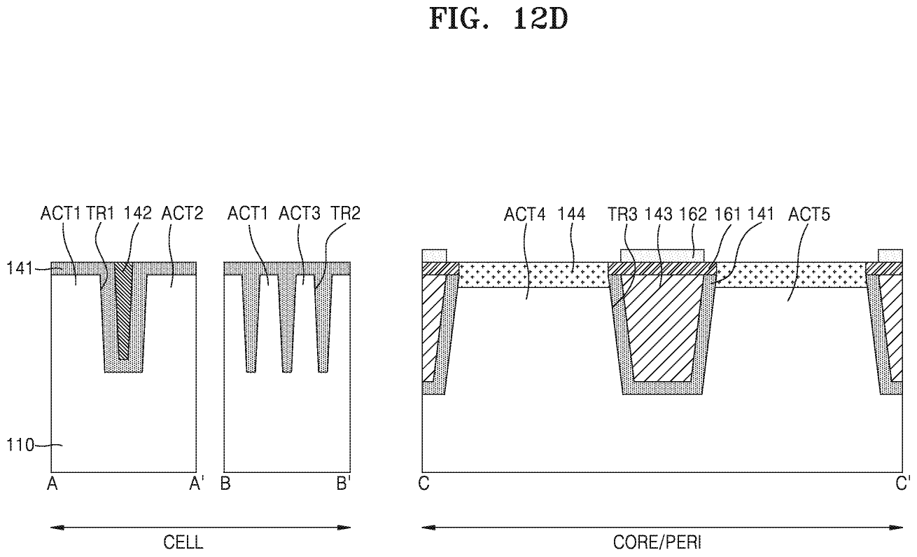

FIGS. 12A through 12D are cross-sectional views of a method of manufacturing a semiconductor device, according to some embodiments of the inventive concepts.

First, processes depicted in FIGS. 11A through 11I may be performed. Afterwards, as depicted in FIG. 12A, a second nitride film 161 may be formed. The second nitride film 161 may be deposited by using an ALD method, a CVD method, a PECVD method, or a combination of these methods.

Referring to FIG. 12B, a fourth oxide film 162 may be formed on the second nitride film 161. The fourth oxide film 162 may be formed by heat treating a fluid material after coating the fluid material, for example, TOSZ, on the second nitride film 161.

Referring to FIG. 12C, the fourth oxide film 162 may be polished by using, for example, a CMP process so that the second nitride film 161 is exposed. All of the fourth oxide film 162 in the cell region CELL may be removed. A portion of the fourth oxide film 162 in the core/peripheral region CORE/PERI may remain. This is because an upper surface 144U of the third oxide film 144, an upper surface 143U of the second oxide film 143, and an upper surface 141U of the first oxide film 141 are not a coplanar surface but form an uneven surface.

Referring to FIG. 12D, the second nitride film 161 may be etched. All of the second nitride film 161 in the cell region CELL may be removed. Of the second nitride film 161 in the core/peripheral region CORE/PERI, a portion of the second nitride film 161 covered by the fourth oxide film 162, or a portion of the second nitride film 161 having a large thickness before etching, for example, the portion of the second nitride film 161 that contacts the first oxide film 141, may partly remain.

Referring to FIGS. 12D and 9, an upper part of the first oxide film 141 and an upper part of the first nitride film 142 in the cell region CELL and the third oxide film 144 and the fourth oxide film 162 in the core/peripheral region CORE/PERI may be removed. Thus, the first device isolation layer IL1 and the second device isolation layer IL2 depicted in FIG. 9 may be formed. That is, the first oxide film 141 and the first nitride film 142 in the cell region CELL of FIG. 12D may form the first insulating film 131 and the second insulating film 132 respectively of the first device isolation layer IL1 in the cell region CELL of FIG. 9. Also, the first oxide film 141, the second oxide film 143, and the second nitride film 161 in the core/peripheral region CORE/PERI of FIG. 12D may form the third insulating film 151, the fourth insulating film 152, and the capping insulating film 153 respectively of the second device isolation layer IL2 in the core/peripheral region CORE/PERI.

The capping insulating film 153 of FIG. 9 may reduce or prevent the third insulating film 151 and the fourth insulating film 152 under the capping insulating film 153 from being etched during etching the third oxide film 144 and the fourth oxide film 162. Accordingly, reduction of heights of upper ends of the third insulating film 151 and the fourth insulating film 152 or formation of depressed upper surfaces of the third insulating film 151 and the fourth insulating film 152 may be reduced or prevented.

While the inventive concepts have been particularly shown and described with reference to embodiments thereof, it will be understood that the technical scope of the inventive concepts is not limited by the embodiments. The scope of the inventive concepts should be defined by the appended claims, and all differences within the scope will be construed as being included in the inventive concepts.

What is claimed is:

1. A semiconductor device comprising:
a substrate having a cell region and a core/peripheral region;
a first active region in the cell region of the substrate;
a first device isolation layer that defines the first active region;
a second active region in the core/peripheral region of the substrate; and
a second device isolation layer that defines the second active region,
wherein, the second device isolation layer comprises a first insulating film that contacts the second active region and a second insulating film that contacts the first insulating film and is spaced apart from the first active region,
a height from a lower surface of the substrate to an upper end of the first device isolation layer in a first direction perpendicular to the lower surface of the substrate is less than or equal to a height from the lower surface of the substrate to an upper end of the first active region in the first direction, and
a height from the lower surface of the substrate to an upper end of the second device isolation layer in the first direction is greater than a height from the lower surface of the substrate to an upper end of the second active region in the first direction.

2. The semiconductor device of claim 1, wherein, in the core/peripheral region, a height from the lower surface of the substrate to an upper portion of the first insulating film in the first direction and a height from the lower surface of the substrate to an upper portion of the second insulating film in the first direction are greater than the height from the lower surface of the substrate to the upper end of the second active region in the first direction.

3. The semiconductor device of claim 1, wherein the first insulating film and the second insulating film comprise a silicon oxide.

4. The semiconductor device of claim 1, wherein an upper surface of the second device isolation layer comprises a dent having a shape depressed in a direction opposite to the first direction.

5. The semiconductor device of claim 4, wherein the upper surface of the second device isolation layer further comprises a sloped portion between the second active region and the dent and inclined towards the dent with respect to the first direction.

6. The semiconductor device of claim 4, wherein a height from the lower surface of the substrate to a lower end of the dent of the upper surface of the second device isolation layer in the first direction is greater than the height from the lower surface of the substrate to the upper end of the second active region in the first direction.

7. The semiconductor device of claim 1, wherein the height from the lower surface of the substrate to the upper end of the first active region in the first direction is greater than the height from the lower surface of the substrate to the upper end of the second active region in the first direction.

8. A semiconductor device comprising:
a substrate having a cell region and a core/peripheral region;
a first active region in the cell region of the substrate;
a second active region separated by a first distance from the first active region in a direction parallel to a lower surface of the substrate;
a third active region separated by a second distance from the first active region in a direction parallel to the lower surface of the substrate, the second distance being less than the first distance;
a first device isolation layer that defines the first active region, the second active region, and the third active region;
a fourth active region and a fifth active region separated from each other by a third distance in a direction parallel to the lower surface of the substrate in the core/peripheral region of the substrate, the third distance being greater than the first distance; and
a second device isolation layer that defines the fourth active region and the fifth active region,
wherein the first device isolation layer comprises a first insulating film that contacts the first active region, the second active region, and the third active region and a second insulating film surrounded by the first insulating film,
the second insulating film between the first active region and the second active region,
the second device isolation layer comprises a third insulating film that contacts the fourth active region and the fifth active region and a fourth insulating film that contacts the third insulating film and separated from the fourth active region and the fifth active region, and
at least a portion of an upper surface of the second device isolation layer upwardly protrudes from the fourth active region and the fifth active region.

9. The semiconductor device of claim 8, wherein the third insulating film and the fourth insulating film comprise the same material.

10. The semiconductor device of claim 8, wherein the entire upper surface of the second device isolation layer upwardly protrudes from the fourth active region and the fifth active region.

11. The semiconductor device of claim 8, wherein a distance that at least a portion of the upper surface of the second device isolation layer upwardly protrudes from the fourth active region and the fifth active region is less than the third distance between the fourth active region and the fifth active region.

12. The semiconductor device of claim 8, wherein the upper surface of the second device isolation layer has a dent having a shape downwardly depressed as much as a first depth, and
the first depth is less than the third distance between the fourth active region and the fifth active region.

13. The semiconductor device of claim 8, wherein the first insulating film, the third insulating film, and the fourth insulating film comprise the same material.

14. A semiconductor device comprising:
a substrate having a cell region and a core/peripheral region;
a first active region in the cell region of the substrate;
a first device isolation layer that defines the first active region;
a second active region in the core/peripheral region of the substrate;
a second device isolation layer that defines the second active region;
a gate insulating film on the second active region; and
a gate structure arranged on the gate insulating film and extends on the second device isolation layer,
wherein the first device isolation layer comprises a first insulating film that contacts the first active region and a second insulating film surrounded by the first insulating film,
the second device isolation layer comprises a third insulating film that contacts the second active region, a fourth insulating film, sidewalls and a lower surface of which are surrounded by the third insulating film, and a capping insulating film covering an upper surface of the fourth insulating film,
a height from a lower surface of the substrate to an upper end of the second device isolation layer in a first direction perpendicular to the lower surface of the substrate is greater than a height from the lower surface of the substrate to an upper end of the second active region in the first direction, and
a height from the lower surface of the substrate to an upper end of the first active region in the first direction is greater than a height from the lower surface of the substrate to the upper end of the second active region in the first direction.

15. The semiconductor device of claim 14, wherein the gate structure contacts the third insulating film and the capping insulating film of the second device isolation layer.

16. The semiconductor device of claim 14, wherein the capping insulating film of the second device isolation layer contacts the third insulating film and the fourth insulating film.

17. The semiconductor device of claim 14, wherein the capping insulating film of the second device isolation layer is separate from the second active region.

18. The semiconductor device of claim 14, wherein a thickness of the gate structure in the first direction is greater than a distance between the upper end of the second active region to the upper end of the second device isolation layer in the first direction.

19. The semiconductor device of claim 14, wherein at least a portion of the third insulating film and at least a portion of the fourth insulating film of the second device isolation layer upwardly protrude from the second active region.

20. The semiconductor device of claim 14, wherein the capping insulating film of the second device isolation layer comprises the same material as the second insulating film of the first device isolation layer.
